(19) United States
(12) Patent Application Publication
(10) Pub. No.: US 2025/0054827 A1
(43) Pub. Date: Feb. 13, 2025

(54) STACKED MULTI-CHIP STRUCTURE WITH ENHANCED PROTECTION

(71) Applicant: Vishay General Semiconductor, LLC, Malvern, PA (US)

(72) Inventors: Wan-Lan CHIANG, Taipei (TW); Ming-Tai CHIANG, Taipei (TW); Chun-Ta LEE, Taipei (TW)

(73) Assignee: Vishay General Semiconductor, LLC, Malvern, PA (US)

(21) Appl. No.: 18/717,681

(22) PCT Filed: Dec. 10, 2021
(86) PCT No.: PCT/US2021/062765

§ 371 Date: Jun. 7, 2024

(51) Int. Cl. H01L 23/31; H01L 21/56; H01L 23/00; H01L 23/29; H01L 23/495; H01L 25/065

(52) U.S. Cl. CPC H01L 23/3135; H01L 21/56; H01L 23/49575; H01L 24/32; H01L 24/33; H01L 24/83; H01L 25/0657; H01L 23/296; H01L 2224/32145; H01L 2224/32245; H01L 2224/33181; H01L 2224/83193; H01L 2225/06565

(57) ABSTRACT

A stacked multi-chip electronic assembly with an electronic component sub-assembly. having components, including a conductive top clip, first and second semiconductor chips, and a conductive bottom clip assembled in a stacked arrangement. Solder layers are located between facing contact surfaces of the components in the stacked arrangement. Once soldered together, this forms the electronic component sub-assembly. A polymer layer extends between the conductive top clip and the conductive bottom clip encapsulating sides of the first and second semiconductor chips and the solder layers. This polymer layer protects and/or seals exposed chip surfaces to inhibit mechanical damage from further processes, and protects the chip passivation surface(s) from ionic contamination that may be introduced from further assembly processes. A package is formed from a molding compound to encapsulate the electronic component sub-assembly and the polymer layer, with leads from the conductive top and bottom clips extending outside of the body.

### FIELD OF INVENTION

This application relates to the field of electronic components, particularly to TVS (transient-voltage-suppression) and Zener devices, and more particularly to stacked chips arranged in a single package, used in various applications, such as high surge power TVS in automotive, telecom base station, and 5G base station applications, high voltage TVS in electric car, hybrid car, and charge station applications, and low clamping TVS in automotive, electric car, hybrid car, charge station, robotics, as well as other applications.

### BACKGROUND

Electronic components, such as TVS diodes are used in a number of applications for protection of other semiconductor components from high-voltage transients. Zener diodes are also known and commonly used for voltage regulation, surge suppressors, and various other applications.

These as well as other electronic components may be formed as surface mountable devices for PCB applications. Here, the active chip component is located in a package, molded of a suitable polymer, and leads extend from the chip out of the package to a bottom surface thereof for connection to the PCB.

Certain applications have limited space on the PCB, so it is also known to have multi-chip packages in which, for example two or more TVS chips are stacked on top of one another and the contact surfaces of the chips are soldered together and to appropriate leads. This allows for higher capacity and/or higher power components to packaged into a smaller footprint, ultimately resulting in less space needed on the PCB, allowing the size to be reduced or other features/components added while maintaining the same size.

For such applications with stacked chips located in the package, it would be desirable to provide improved in-service reliability.

### SUMMARY

A stacked multi-chip electronic assembly is provided having an electronic component sub-assembly. The electronic component sub-assembly includes components, including a conductive top clip having a bottom contact surface and a lead, at least first and second semiconductor chips, each having top and bottom contact surfaces, as well as a conductive bottom clip having a top contact surface and a lead, with these components assembled in a stacked arrangement. The at least first and second semiconductor chips can be for example, TVS, Zener, or other electronic devices. Solder layers are located between facing ones of the contact surfaces of the components in the stacked arrangement. In the embodiment with only first and second semiconductor chips, the solder layers are located between (a) the top contact surface of the conductive bottom clip and the bottom contact surface of the first semiconductor chip, (b) the top contact surface of the first semiconductor chip and the bottom contact surface of the second semiconductor chip, and (c) the top contact surface of the second semiconductor chip and the bottom contact surface of the conductive top clip to electrically connect the components together. Once soldered together, this forms the electronic component sub-assembly. A polymer layer is provided that extends between the conductive top clip and the conductive bottom clip encapsulating sides of the first and second semiconductor chips and the solder layers located therebetween. This polymer layer acts as a protection layer to protect and/or seal the exposed chip surfaces to inhibit any mechanical damages from processes which follow, such as the mold compound application process to form the package, as well as to protect the chip passivation surface from any ionic contamination that may be introduced from the successive assembly process. A body (or package) is formed from a molding compound to encapsulate the electronic component sub-assembly and the polymer layer. At least a portion of the leads from the conductive top and bottom clips extending outside of the body.

In one embodiment, the polymer layer extends around the bottom contact surface of the conductive top clip and the top contact surface of the conductive bottom clip.

In a further embodiment, the bottom contact surface of the conductive top clip includes a protruding portion that forms a chip contact area, and the top contact surface of the conductive bottom clip includes a protruding portion that forms a chip contact area, and the polymer layer surrounds edges of these protruding portions. This provides a more robust construction due to the contact area provided by the sides of the protruding portions where the polymer layer can adhere.

In one preferred arrangement, the polymer layer comprises a polyimide silicon. However, other polymers could also be used. It is also possible to use various polymers with or without a filler in order to achieve a desired coefficient of thermal expansion for the particular application.

In one preferred arrangement, the molding compound is an epoxy molding compound. However, other polymeric materials with or without filler could be used

In a preferred arrangement, the portions of the leads from the conductive top and bottom clips that extend outside of the body include respective end portions that extend along a bottom surface of the body. This is preferred for PCB applications. However, for other applications, it is not necessary for the leads to extend along a common surface.

In another embodiment, additional components are provided in the stacked arrangement in the form of copper slugs that are located at least one: between the bottom contact surface of the conductive top clip and the top contact surface of the second semiconductor chip, between the contact surfaces of adjacent ones of the semiconductor chips, or between the bottom contact surface of the first semiconductor chip and the top contact surface of the conductive bottom clip. Here, the solder layers are located between each of the contact surfaces and the copper slugs in order to provide conductive contact between the stacked components and the copper slugs.

Multichip stacked electronic assemblies may include TVS and/or Zener devices in various packages and other surface mount or axial lead devices. The electronic component sub-assembly can be comprised of components including two or more chips, or chips with copper slugs located therebetween that are located between the conductive top and bottom clips. The copper slugs provide a heat absorption reservoir for TVS surge capability enhancement as well as protect the chip edge from mechanical impact damage.

The multichip stacked electronic assemblies have many applications. For chips that are TVS or Zener devices, potential applications include high surge power TVS, high voltage TVS, Low Clamping TVS, asymmetric voltage TVS or just to quickly meeting the voltage target from the stacked-chip combination. Such multichip stacked electronic assemblies may also be applied to other power rectifier application as well.

In another aspect, a method of assembling a stacked multi-chip electronic assembly is provided. The method includes assembling an electronic component sub-assembly with components in a stacked arrangement, with the components including a conductive bottom clip having a top contact surface and a lead, at least first and second semiconductor chips, each having top and bottom contact surfaces, a conductive top clip having a bottom contact surface and a lead, and applying solder layers between facing ones of the contact surfaces of the components in the stacked arrangement. In order to provide enhanced protection to the exposed chip surfaces, the method further includes applying a polymer layer between the conductive top clip and the conductive bottom clip encapsulating sides of the first and second semiconductor chips and the solder layers located therebetween. Additionally, the method includes molding a body from a molding compound that encapsulates the electronic component sub-assembly and the polymer layer, with at least a portion of the leads from the conductive top and bottom clips extending outside of the body. The molding of the body is preferably done in the conventional manner.

For the electronic component sub-assembly with only the first and second semiconductor chips as the active components, the applying of the solder layers includes applying the solder layers between a) the top contact surface of the conductive bottom clip and the bottom contact surface of the first semiconductor chip, (b) the top contact surface of the first semiconductor chip and the bottom contact surface of the second semiconductor chip, and (c) the top contact surface of the second semiconductor chip and the bottom contact surface of the conductive top clip.

In another aspect, a stacked multi-chip electronic assembly is provided having an electronic component sub-assembly with components including: at least first and second semiconductor chips, each having top and bottom contact surfaces, and a solder layer located between facing ones of the contact surfaces of the components in the stacked arrangement. A polymer layer encapsulates sides of the at least first and second semi-conductor chips and the solder layer located therebetween.

In one embodiment, the components further include copper slugs located at least one of: on the top contact surface of the second semiconductor chip, between the contact surfaces of adjacent ones of the semiconductor chips, or on the bottom contact surface of the first semiconductor chip. Here, the solder layers are located between each of the contact surfaces and the copper slugs.

### BRIEF DESCRIPTION OF THE DRAWING(S)

The foregoing aspects and many of the accompanying advantages of this invention will become more readily appreciated as the same becomes better understood by reference to the following detailed description when taken in conjunction with the accompanying drawings, wherein:

FIG. 1 is a cross-sectional view of a first embodiment of a stacked multi-chip electronic assembly.

FIG. 2 is a cross-sectional view corresponding to a sample according to FIG. 1.

FIG. 3 is a cross-sectional view of a second embodiment of a stacked multi-chip electronic assembly.

FIG. 4 is a cross-sectional view of a third embodiment of a stacked multi-chip electronic assembly.

FIG. 5 is a cross-sectional view of an electronic component sub-assembly having several stacked electronic components and a polymer layer protecting the sides of the electronic components.

FIG. 6 is a flow chart showing a method of assembling the stacked multi-chip electronic assembly.

### DETAILED DESCRIPTION

Certain terminology is used in the following description for convenience only and is not limiting. The words “right,” “left,” “top,” and “bottom” designate directions in the drawings to which reference is made. The words “a” and “one,” as used in the claims and in the corresponding portions of the specification, are defined as including one or more of the referenced item unless specifically stated otherwise. This terminology includes the words above specifically mentioned, derivatives thereof, and words of similar import. The phrase “at least one” followed by a list of two or more items, such as “A, B, or C,” means any individual one of A, B or C as well as any combination thereof. It may be noted that some Figures are shown with partial transparency for the purpose of explanation, illustration and demonstration purposes only, and is not intended to indicate that an element itself would be transparent in its final manufactured form.

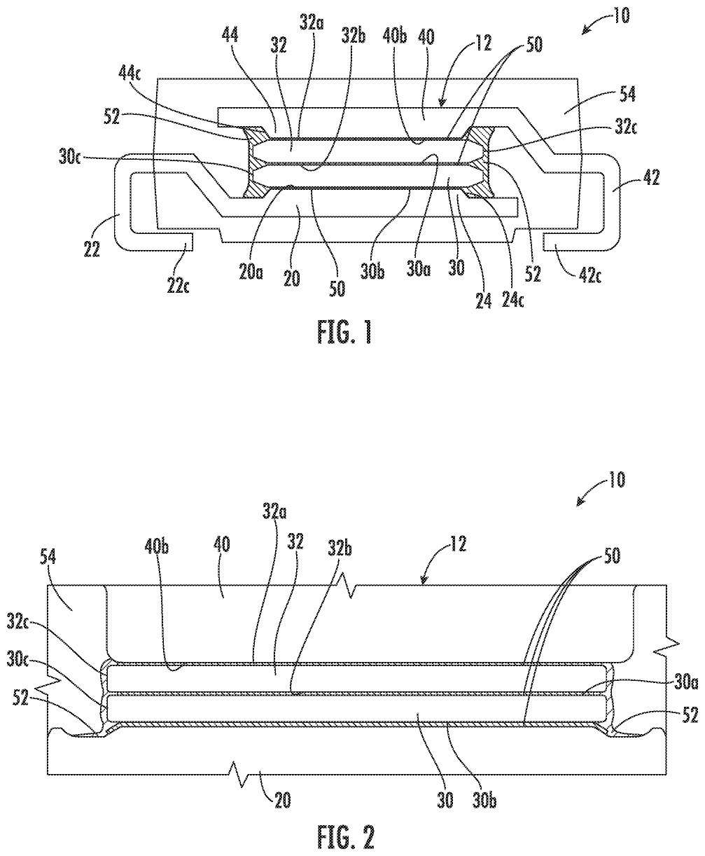

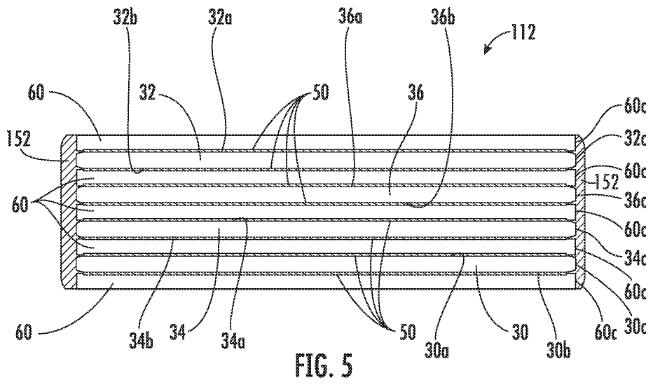

Referring to FIGS. 1 and 2, a first embodiment of a stacked multi-chip electronic assembly 10 is shown. FIG. 1 is a cross-sectional view showing one configuration while FIG. 2 is a view corresponding to an actual cross-section sample of the first embodiment of the stacked multi-chip electronic assembly 10.

The stacked multi-chip electronic assembly 10 includes an electronic component sub-assembly 12 having several components that are stacked together. These include a conductive bottom clip or pad 20 having a top contact surface 20a and a lead 22, at least first and second semi-conductor chips 30, 32, each having a top contact surface 30a, 32a and a bottom contact surface 30b, 32b, as well as a conductive top clip 40 having a bottom contact surface 40b and a lead 42. These components are stacked together. The conductive bottom clip 20 and the conductive top clip 40 are preferably made from copper or a copper alloy. However, other conductive materials could be used. The first and second semiconductor chips 30, 32 can be, for example, TVS, Zener, or other electronic devices. While first and second semiconductor chips 30, 32 are shown in the first embodiment of the electronic assembly 10, additional semiconductor chips could be provided, as explained in further detail below.

The above components form a series arrangement and solder layers 50 are located between facing ones of the contact surfaces 20a, 30b; 30a, 32b; and 32a, 40b of these components that are in the stacked arrangement. In the first embodiment of the electronic assembly 10 where there are only first and second semiconductor chips 30, 32, the solder layers 50 are located between (a) a top contact surface 20a of the conductive bottom clip 20 and a bottom contact surface 30b of this first semiconductor chip 30, (b) the top contact surface 30a of the first semiconductor chip 30 and the bottom contact surface 32b of the second semiconductor chip 32, and (c) the top contact surface 32a of the second semiconductor chip 32 and a bottom contact surface 40b of the conductive top clip 40.

In order to add a protection layer to protect and/or seal the exposed chip surfaces to inhibit mechanical damage from further processing, such as the molding step of the body or package 54 around the electronic component sub-assembly 12, as well as to protect the chip passivation surface from any ionic contamination, a polymer layer 52 is provided that extends between the top conductive clip 40 and the bottom conductive clip 20 encapsulating sides 30c, 32c of the first and second semiconductor chips 30, 32 as well as edges of the solder layers 50 located therebetween. In the first embodiment of the electronic assembly 10, this polymer layer 52 extends around the bottom contact surface 40b of the conductive top clip 40 and the top contact surface 20a of the conductive clip 20 in order to encapsulate the sides 30c, 32c of the first and second semiconductor chips 30, 32 as well as the edges of the solder layers 50. Here, in order to provide a more robust construction, the bottom contact surface 40b of the conductive top chip 40 may include a protruding portion 44 (Shown in FIG. 1) that forms a chip contact area, and the top contact surface 20a of the conductive bottom clip 20 may include a protruding portion 24 (shown in FIG. 1) that forms a chip contact area, and the polymer layer 52 surrounds edges 24c, 44c of the protruding portions 24, 44, as shown in FIG. 1. Alternatively, as shown in FIG. 2, these protruding portions 24, 44 can be omitted and the polymer layer can merely extend from the edge of the contact surface 40b of the conductive top clip 40 to the edge of the top contact surface 20a of the conductive bottom clip 20.

In one preferred embodiment the polymer layer comprises a polyimide silicon. Other polymers could also be used with or without filling materials, such as a ceramic filler in order to achieve the desired adhesion properties along with a desired co-efficient of thermal expansion depending on the particular application.

Still with reference to FIGS. 1 and 2, a body 54 is formed from a molding compound that encapsulates the electronic component sub-assembly 12 and the polymer layer 52, with at least a portion of the leads 22, 42 from the conductive bottom and top clips 20, 40 extending outside of the body 54. As shown in FIG. 1, portions of the leads 22, 42 from the conductive bottom and top clips 20, 40 that extend outside of the body 54 include respective end portions 22c, 42c that extend along a bottom surface of the body 54. This is useful for surface mounted electronic assemblies 10 however, the leads 22, 42 could extend straight out from the sides of the bodies for other types of electronic assemblies.

In the preferred embodiment, the molding compound is an epoxy molding compound. However, other polymeric materials with or without fillers could be used.

Referring now to FIG. 3, a second embodiment of a stacked multi-chip electronic assembly 10′ is shown. The second embodiment of the electronic assembly 10′ is similar to the first embodiment of the electronic assembly 10 discussed above. However, in this case the components of electronic component sub-assembly 12′ include two additional semiconductor chips 34, 36 located between the first and second semiconductor chips 30, 32 in the stacked arrangement. These two additional semiconductor chips 34, 36 each have a top contact surface 34a, 36a as well as a bottom contact surface 34b, 36b. Additionally, the components of electronic component sub-assembly 12′ further include copper slugs 60 located at least one of between the bottom contact surface 40b of the top conductive clip 40 and the top contact surface 32a of the second semiconductor chip 32, between the contact surfaces 30a, 34b; 34a, 36b; 36a, 32b; of adjacent ones of the semiconductor chips 30, 32, 34, 36, or between the bottom contact surface 30b of the first semiconductor chip 30 and the top contact surface 20a of the conductive bottom clip 20. In the illustrated embodiment, the copper slugs 60 are located in each of these locations; however, this is not required and the copper slugs 60 could be located in only some of the locations. For example, the copper slugs 60 could be located only between the bottom contact surface 40b of the top conductive clip 40 and the top contact surface 32a of the second semiconductor chip 32 and between the bottom contact surface 30b of the first semiconductor chip 30 and the top contact surface 20a of the conductive bottom clip 20. The sides 60c of the copper slugs 60 extend at least as far as the sides 30c, 32c, 34c, 36c of the semiconductor chips 30, 32, 34, 36 in order to protect the sides 30c, 32c, 34c, 36c of the semiconductor chips 30, 32, 34, 36 from mechanical impact damage. Here, the solder layers 50 are located between each of the contact surfaces of the bottom conductive clip 20, the semiconductor chips 30, 32, 34, 36, the top conductive clip 40 and the facing contact surfaces of the copper slugs 60.

Still with reference to FIG. 3, in this case, the polymer layer 52′ extends around the bottom contact surface 40b of the top conductive clip 40 and the top contact surface 20a of the bottom conductive clip 20 and encapsulates sides 30c, 32c, 34c, 36c of the semiconductor chips 30, 32, 34, 36, as well as sides 60c of the copper slug 60 and the edges of the solder layers 50.

A body 54′ is formed from a molding compound that encapsulates the electronic component sub-assembly 12′ and the polymer layer 52′, with at least a portion of the leads 22, 42 from the conductive bottom and top clips 20, 40 extending outside of the body 54′.

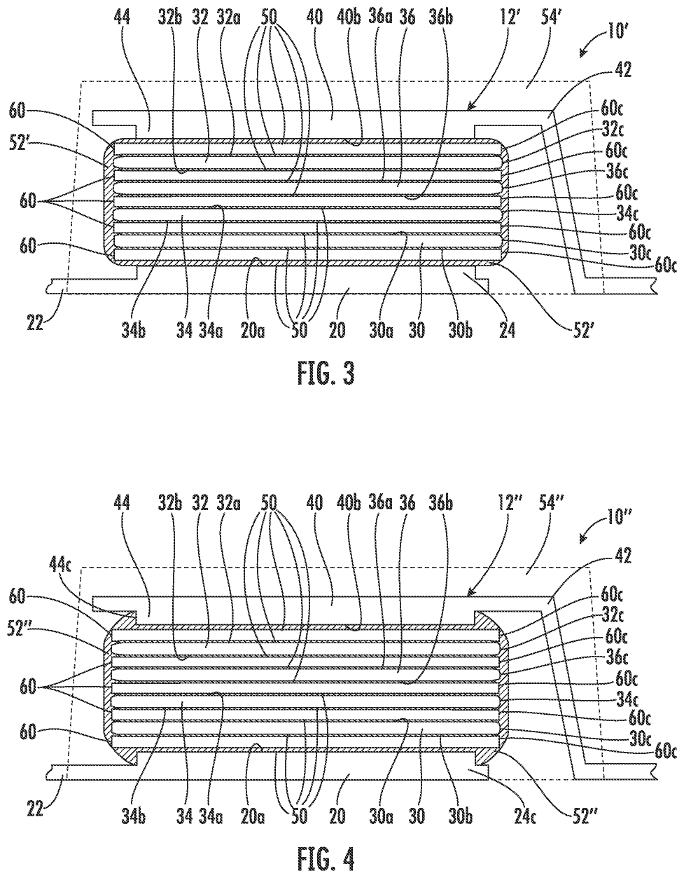

Referring to FIG. 4, the third embodiment of the stacked multi-chip electronic assembly 10″ is shown. This third embodiment of the electronic assembly 10″ is similar to the second embodiment 10′, and includes the electronic component sub-assembly 12″ which is formed in the same manner as the electronic component sub-assembly 12′ noted above. However, in this embodiment, the polymer layer 52″ surrounds edges 24c, 44c of the protruding portions 24, 44 of the bottom and top conductive clips 20, 40, respectively. This arrangement provides more contact area for the polymer layer 52″ with the conductive clips 20, 40 providing a more robust arrangement.

A body 54″ is formed from a molding compound that encapsulates the electronic component sub-assembly 12″ and the polymer layer 52″, with at least a portion of the leads 22, 42 from the conductive bottom and top clips 20, 40 extending outside of the body 54″.

Referring now to FIG. 5, an electronic component sub-assembly 112 is shown that is similar to the electronic component sub-assembly 12′ described above, except that separate conductor attachments are not provided as part of the components in the stacked arrangement. The sub-assembly 112 can be integrated into a discrete package or into a module, or have conductors similar to or different from the conductive clips 20, 40 discussed above attached in a later manufacturing step. Here, the electronic component sub-assembly 112 includes the semiconductor chips 30, 32, 34, 36 as discussed above, although fewer or more of the semiconductor chips could be used, as well as the copper slugs 60 located at least one of on the top contact surface 32a of the second semiconductor chip 32, between the contact surfaces 30a, 34b; 34a, 36b; 36a, 32b; of adjacent ones of the semiconductor chips 30, 32, 34, 36, or on the bottom contact surface 30b of the first semiconductor chip 30. In the illustrated embodiment, the copper slugs 60 are located in each of these locations; however, this is not required and the copper slugs 60 could be located in only some of the locations. For example, the copper slugs 60 could be located only on the top contact surface 32a of the second semiconductor chip 32 and on the bottom contact surface 30b of the first semiconductor chip 30. Alternatively, the copper slugs could be omitted.

The sides 60c of the copper slugs 60 extend at least as far as the sides 30c, 32c, 34c, 36c of the semiconductor chips 30, 32, 34, 36 in order to protect the sides 30c, 32c, 34c, 36c of the semiconductor chips 30, 32, 34, 36 from mechanical impact damage. Here, the solder layers 50 are located between each of the contact surfaces of the semiconductor chips 30, 32, 34, 36 and the facing contact surfaces of the copper slugs 60.

Still with reference to FIG. 5, in this case, the polymer layer 152 encapsulates sides 30c, 32c, 34c, 36c of the semiconductor chips 30, 32, 34, 36, as well as sides 60c of the copper slug 60 and the edges of the solder layers 50. Those skilled in the art will recognize that the number of semiconductor chips 30, 32, 34, 36 in the electronic component sub-assembly 12, 12′, 12″, 112 can be varied, and, for example, 5 semiconductor chips, 6 semiconductor chips, or more could be provided in the electronic component sub-assembly, and that the use of copper slugs 60 is optional, depending upon the particular application.

Additionally, while the polymer layer 52, 52′, 52″, 152 in the disclosed embodiments encapsulates all of the sides of the semiconductor chips 30, 32, 34, 36 as well as the edges of the solder layers 50 and the sides 60c of the copper slugs 60, if present in the electronic component sub-assemblies 12, 12′, 12″, some of the benefits of the present invention could still be achieved if the polymer layer was applied to less than all of the sides and edges.

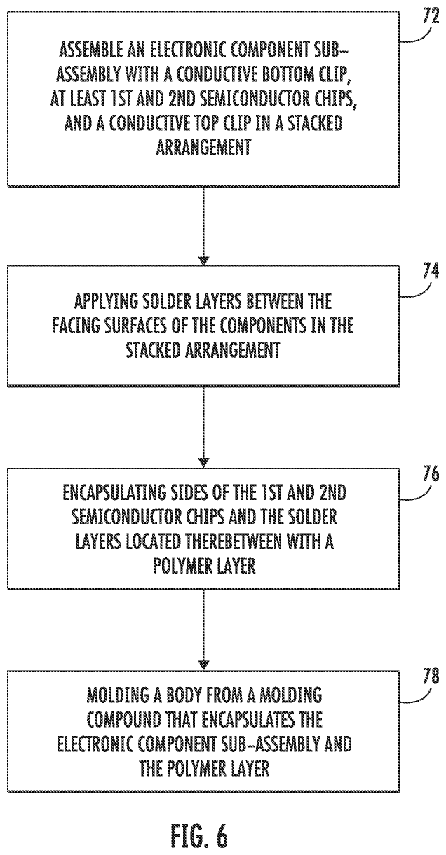

Referring now to FIG. 6, a method of assembling a stacked multi-chip electronic assembly 10, 10′, 10″ is provided. The method includes assembling an electronic component sub-assembly 12, 12′, 12″ with components 20, 30, 32, 34, 36, 60, and 40 (as well as optionally 60) in a stacked arrangement. The components include a conductive bottom clip 20 having a top contact surface 20a and a lead 22 as well as at least the first and second semiconductor chips 30, 32, although additional semiconductor chips 34, 36, etc., can be provided, each having top contact surfaces 30a, 32a, 34a, 36a, and bottom contact surfaces 30b, 32b, 34b, 36b, as well as a conductive top clip 40 having a bottom contact surface 40b and a lead 42. This is shown at 72 in FIG. 6. These components are arranged in the stacked arrangement.

As noted at 74, solder layers 50 are applied between facing ones of the contact surfaces of the components in the stacked arrangement to form the electronic component sub-assembly 12, 12′, 12″.

In order to provide a more robust assembly to protect and/or the exposed chip surfaces and to inhibit mechanical damage from further processing as well as to protect the chip passivation surface from any ionic contamination that may be introduced from the successive assembly process, a polymer layer 52, 52′, 52″ is applied between the conductive top clip 40 and the conductive bottom clip 20 encapsulating sides 30c, 32c of the first and second semiconductor chips 30, 32 as well as the sides 34c, 36c of any additional semiconductor chips 34, 36 as well as edges of the solder layers 50 located therebetween. This is indicated at 76 in FIG. 6. The sides 60c of the copper slugs 60 are also encapsulated, if present. The polymer layer 52, 52′, can extend around the bottom contact surface 40b of the top conductive clip 40 and the top contact surface of the conductive bottom clip 20 as shown, for example, in FIGS. 2 and 3, or can extend around the edges 24c, 44c of the protruding portions 24, 44 of the bottom and top conductive clips 20, 40 as shown in FIGS. 1 and 4 in order to provide a greater surface area for contact with the conductive bottom and top clips 20, 40.

As indicated at 78, the method further includes molding a body 54, 54′, 54″ from a molding compound that encapsulates the electronic component sub-assembly 12, 12′, 12″ and the polymer layer, with at least a portion of the leads 22, 42 from the conductive top and bottom clips 40, 20 extending outside of the body 54.

The method can further include the assembling of the electronic component sub-assembly 12′, 12″ including locating the copper slugs 60 at least one of: between the bottom contact surface 40b of the top conductive clip 40 and the top contact surface 32a of the second semiconductor chip 32, between the contact surfaces 32b, 36a; 36b, 34a; 34b, 30a of adjacent ones of the semiconductor chips 30, 32 (as well as any additional semiconductor chips 34, 36), or between the bottom contact surface 30b of the first semiconductor chip 30 and the top contact surface 20a of the bottom conductive clip 20. The method would then include applying the solder layers 50 between each of the facing contact surfaces and the copper slugs 60.

The manufacture of the electronic component sub-assembly 112 shown in FIG. 5 can be carried out in a similar manner to steps 72, 74 and 76 above, without the conductive clips 20, 40 in the stacked arrangement.

It will be appreciated that the foregoing is presented by way of illustration only and not by way of any limitation. It is contemplated that various alternatives and modifications may be made to the described embodiments without departing from the spirit and scope of the invention. Having thus described the present invention in detail, it is to be appreciated and will be apparent to those skilled in the art that many physical changes, only a few of which are exemplified in the detailed description of the invention, could be made without altering the inventive concepts and principles embodied therein. It is also to be appreciated that numerous embodiments incorporating only part of the preferred embodiment are possible which do not alter, with respect to those parts, the inventive concepts and principles embodied therein. The present embodiment and optional configurations are therefore to be considered in all respects as exemplary and/or illustrative and not restrictive, the scope of the invention being indicated by the appended claims rather than by the foregoing description, and all alternate embodiments and changes to this embodiment which come within the meaning and range of equivalency of said claims are therefore to be embraced therein.

What is claimed is:

1. A stacked multi-chip electronic assembly, comprising:
an electronic component sub-assembly having components including:
a conductive bottom clip having a top contact surface and a lead,
at least first and second semiconductor chips, each having top and bottom contact surfaces, and
a conductive top clip having a bottom contact surface and a lead arranged in a stacked arrangement;
solder layers located between facing ones of the contact surfaces of the components in the stacked arrangement;
a polymer layer extending between the conductive top clip and the conductive bottom clip encapsulating sides of the first and second semiconductor chips and the solder layers located therebetween; and
a body formed from a molding compound encapsulating the electronic component sub-assembly and the polymer layer, with at least a portion of the leads from the conductive bottom and top clips extending outside of the body.

2. The assembly of claim 1, wherein there are only first and second semiconductor chips and the solder layers are located between (a) the top contact surface of the conductive bottom clip and the bottom contact surface of the first semiconductor chip, (b) the top contact surface of the first semiconductor chip and the bottom contact surface of the second semiconductor chip, and (c) the top contact surface of the second semiconductor chip and the bottom contact surface of the conductive top clip.

3. The assembly of claim 1, wherein the polymer layer extends around the bottom contact surface of the conductive top clip and the top contact surface of the conductive bottom clip.

4. The assembly of claim 3, wherein the bottom contact surface of the conductive top clip includes a protruding portion that forms a chip contact area, and the top contact surface of the conductive bottom clip includes a protruding portion that forms a chip contact area, and the polymer layer surrounds edges of the protruding portions.

5. The assembly of claim 1, wherein the polymer layer comprises a polyimide silicon.

6. The assembly of claim 1, wherein the molding compound is an epoxy molding compound.

7. The assembly of claim 1, wherein the portions of the leads from the conductive top and bottom clips that extend outside of the body include respective end portions that extend along a bottom surface of the body.

8. The assembly of claim 1, wherein the components further include:
copper slugs located at least one of: between the bottom contact surface of the conductive top clip and the top contact surface of the second semiconductor chip, between the contact surfaces of adjacent ones of the semiconductor chips, or between the bottom contact surface of the first semiconductor chip and the top contact surface of the conductive bottom clip; and
wherein the solder layers are located between each of the contact surfaces and the copper slugs.

9. A method of assembling a stacked multi-chip electronic assembly, the method comprising:
assembling an electronic component sub-assembly with components in a stacked arrangement, the components including a conductive bottom clip having a top contact surface and a lead, at least first and second semiconductor chips, each having top and bottom contact surfaces, and a conductive top clip having a bottom contact surface and a lead, and applying solder layers between facing ones of the contact surfaces of the components in the stacked arrangement;
applying a polymer layer between the conductive top clip and the conductive bottom clip encapsulating sides of the first and second semiconductor chips and the solder layers located therebetween; and
molding a body from a molding compound that encapsulates the electronic component sub-assembly and the polymer layer, with at least a portion of the leads from the conductive top and bottom clips extending outside of the body.

10. The method of claim 9, wherein the at least first and second semiconductor chips includes only the first and second semiconductor chips, and the applying of the solder layers includes applying solder layers between (a) the top contact surface of the conductive bottom clip and the bottom contact surface of the first semiconductor chip, (b) the top contact surface of the first semiconductor chip and the bottom contact surface of the second semiconductor chip, and (c) the top contact surface of the second semiconductor chip and the bottom contact surface the conductive top clip.

11. The method of claim 9, wherein the polymer layer extends around the bottom contact surface of the conductive top clip and the top contact surface of the conductive bottom clip.

12. The method of claim 9, wherein the bottom contact surface of the conductive top clip includes a protruding portion that forms a chip contact area, and the top contact surface of the conductive bottom clip includes a protruding portion that forms a chip contact area, and the method further comprises the polymer layer surrounding edges of the protruding portions.

13. The method of claim 9, wherein the polymer layer comprises a polyimide silicon.

14. The method of claim 9, wherein the molding compound is an epoxy molding compound.

15. The method of claim 9, wherein the portions of the leads from the conductive top and bottom clips that extend outside of the body include respective end portions that extend along a bottom surface of the body.

16. The method of claim 9, further comprising:
the assembling of the electronic component sub-assembly further including locating copper slugs at least one of: between the bottom contact surface of the conductive top clip and the top contact surface of the second semiconductor chip, between the contact surfaces of adjacent ones of the semiconductor chips, or between the bottom contact surface of the first semiconductor chip and the top contact surface of the conductive bottom clip; and
the applying of the solder layers includes applying the solder layers between each of the contact surfaces and the copper slugs.

17. A stacked multi-chip electronic assembly, comprising:
an electronic component sub-assembly having components including:
at least first and second semiconductor chips, each having top and bottom contact surfaces, and
a solder layer located between facing ones of the contact surfaces of the components in the stacked arrangement;
a polymer layer encapsulating sides of the at least first and second semiconductor chips and the solder layer located therebetween.

18. The assembly of claim 17, wherein the components further include copper slugs located at least one of: on the top contact surface of the second semiconductor chip, between the contact surfaces of adjacent ones of the semiconductor chips, or on the bottom contact surface of the first semiconductor chip; and
wherein the solder layers are located between each of the contact surfaces and the copper slugs.

19. The assembly of claim 17, wherein the polymer layer comprises a polyimide silicon.
